(19) United States
(12) Patent Application Publication
(10) Pub. No.: US 2025/0167352 A1
(43) Pub. Date: May 22, 2025

(54) Resin Molded Product

(71) Applicant: Alps Alpine Co., Ltd., Tokyo (JP)

(72) Inventors: Takuya SASAKI, Miyagi-ken (JP); Yoshikiyo WATANABE, Miyagi-ken (JP); Masanori FUNAYAMA, Miyagi-ken (JP)

(21) Appl. No.: 19/034,781

(22) Filed: Jan. 23, 2025

Related U.S. Application Data
(63) Continuation of application No. PCT/JP2023/008369, filed on Mar. 6, 2023.

(30) Foreign Application Priority Data
Aug. 2, 2022 (JP) 2022-123571

(51) Int. Cl. H01M 50/121

(52) U.S. Cl. CPC H01M 50/121

(57) ABSTRACT

A resin molded product has a screw tightening portion in a flat-plate shape. The screw tightening portion has: a through-hole, through which a screw passes; an abutting area allocated around the through-hole, the head of the screw abutting the abutting area; a cut portion formed so as to extend from the through-hole in a first direction, which is along a weld line, the cut portion being formed by cutting out part of the abutting area; and a pair of slits formed so as to further extend from the cut portion in the first direction, the pair of slits being symmetric with respect to the weld line.

### CLAIM OF PRIORITY

This application is a Continuation of International Application No. PCT/JP2023/008369 filed on Mar. 6, 2023, which claims benefit of Japanese Patent Application No. 2022-123571 filed on Aug. 2, 2022. The entire contents of each application noted above are hereby incorporated by reference.

### BACKGROUND OF THE INVENTION

### 1. Field of the Invention

The present invention relates to a resin molded product.

### 2. Description of the Related Art

Japanese Unexamined Patent Application Publication No. 2022-59168 below discloses a technology in which, for the purpose of providing a resin molded product that hardly causes a crack starting from a weld line when pressure is applied, in a resin molded product that has a disk-shaped main body having a through-hole at the center, an opening is formed that communicates with the through-hole and extends on an extension of the straight line connecting the center of the through-hole and a gate cut portion together and toward a peripheral portion of the main body, the peripheral portion being separated from the gate cut portion.

With the technology in Japanese Unexamined Patent Application Publication No. 2022-59168, however, stress applied to the weld line cannot be sufficiently released during screw tightening and high stress thereby continues to be applied to the weld line during screw tightening, so there is the fear that a crack occurs along the weld line.

### SUMMARY OF THE INVENTION

A resin molded product in an embodiment has a screw tightening portion in a flat-plate shape. The screw tightening portion has: a through-hole, through which a screw passes; an abutting area allocated around the through-hole, the head of the screw abutting the abutting area; a cut portion formed so as to extend from the through-hole in a first direction, which is along a weld line, the cut portion being formed by cutting out part of the abutting area; and a pair of slits formed so as to further extend from the cut portion in the first direction, the pair of slits being symmetric with respect to the weld line.

The resin molded product in an embodiment can suppress stress applied to a weld line during screw tightening.

### BRIEF DESCRIPTION OF THE DRAWINGS

FIG. 1 is a perspective view of the outside shape of a resin molded product in an embodiment when viewed from above;

FIG. 2 is a perspective view of the outside shape of the resin molded product in an embodiment when viewed from below;

FIG. 3 is an exploded perspective view of the resin molded product in an embodiment;

FIG. 4 is a sectional view of the resin molded product in an embodiment;

FIG. 5 is a bottom view of a battery cover included in a portable device in an embodiment;

FIG. 6 illustrates an example of the battery cover included in the portable device in an embodiment;

FIG. 7 illustrates a first variation of a screw tightening portion included in the portable device in an embodiment; and

FIG. 8 illustrates a second variation of the screw tightening portion included in the portable device in an embodiment.

### DESCRIPTION OF THE PREFERRED EMBODIMENTS

An embodiment will be described below with reference to the drawings.

### Structure of a Portable Device 100

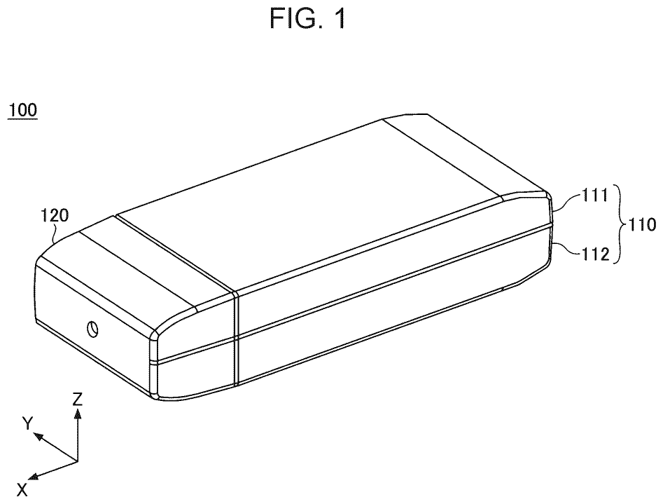

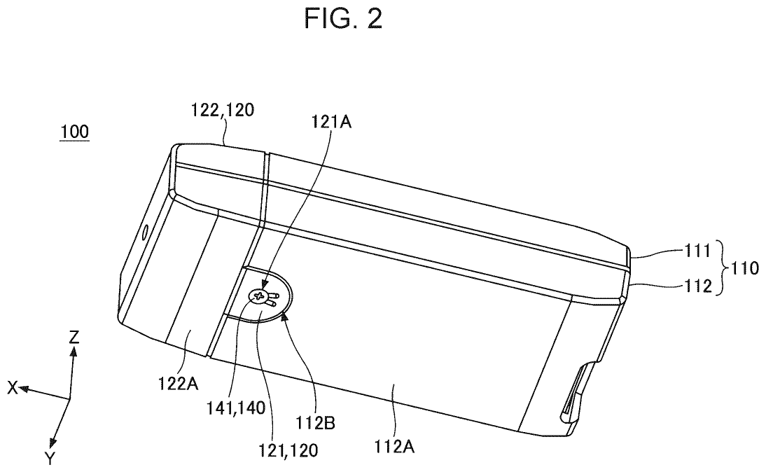

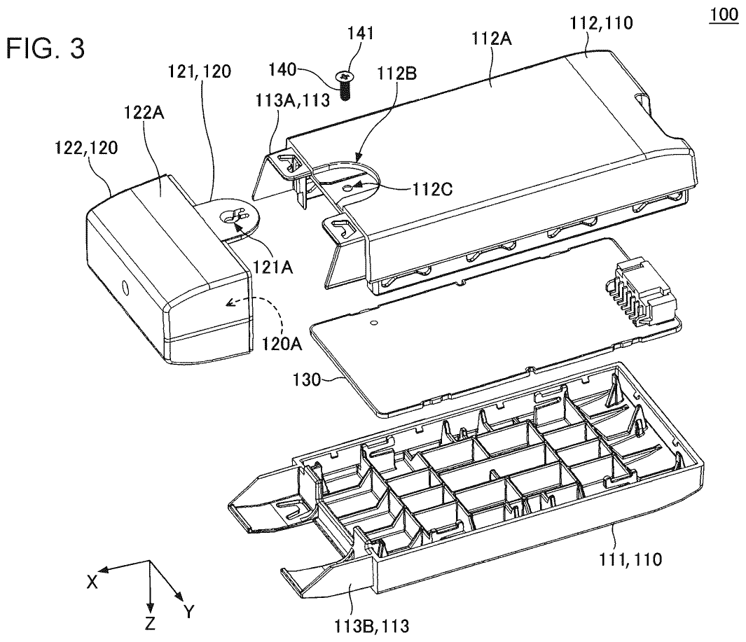

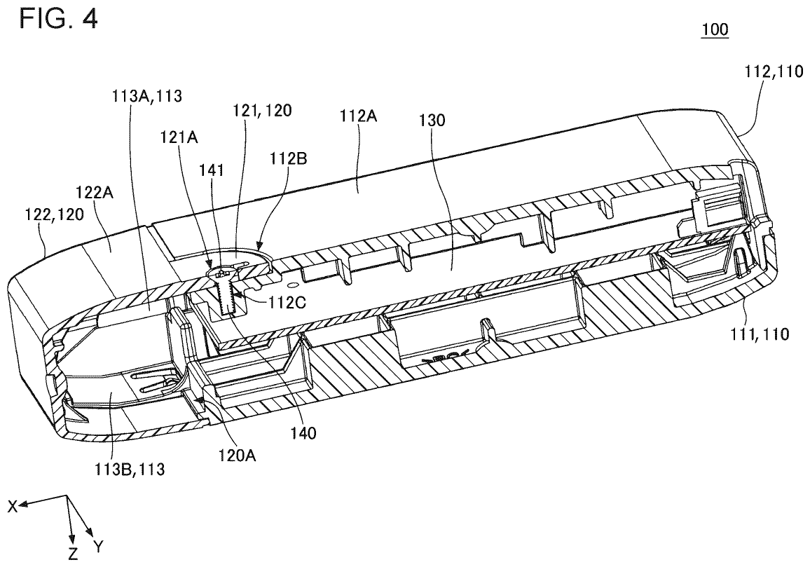

FIG. 1 is a perspective view of the outside shape of a portable device 100 in an embodiment when viewed from above. FIG. 2 is a perspective view of the outside shape of the portable device 100 in an embodiment when viewed from below. FIG. 3 is an exploded perspective view of the portable device 100 in an embodiment. FIG. 4 is a sectional view of the portable device 100 in an embodiment.

In the description below, for the sake of convenience, the Z-axis direction (the thickness direction of a case 110) in the drawings will be taken as the up-down direction, the Y-axis direction (the short-side direction of the case 110) in the drawings will be taken as the lateral width direction, and the X-axis direction (the long-side direction of the case 110) in the drawings will be taken as the front-back direction.

The portable device 100 illustrated in FIG. 1 is a small-sized device that can be carried by the user. An example of the portable device 100 is an electric key that enables a remove manipulation (such as, for example, locking, unlocking, and starting) for a vehicle through wireless communication with a vehicle-mounted machine mounted in the vehicle. Instead of being used as an electronic key, however, the portable device 100 may be used for any other purpose.

As illustrated in FIGS. 1 to 4, the portable device 100 has a case 110, a battery cover 120, and a circuit board 130.

The case 110 is a member, having a hollow structure, that is formed from a resin in a vessel-like shape. The vessel-like shape of the case 110 is a substantially rectangular parallelepiped shape. The case 110 can be divided into two parts, an upper case 111 and a lower case 112, at an intermediate position in the up-down direction. Although the outer shape of the case 110 is in a substantially rectangular parallelepiped shape, its front end (the end on the positive side of the X axis) is cut.

However, a convex portion 113, which is in a substantially angular tubular shape, is formed at the front end (the end on the positive side of the X axis) of the case 110 so as to protrude forward (toward the positive side of the X axis). When the case 110 is divided into two parts, the convex portion 113 can be divided into an upper-convex portion 113A provided integrally with the upper case 111 and a lower-convex portion 113B provided integrally with the lower case 112.

The battery cover 120 is a member, having a hollow structure, that is formed from a resin in a vessel-like shape. The battery cover 120 is an example of a resin molded product. The battery cover 120 has an outer shape contiguous to the case 110 (that is, an outer shape that covers the cut portion of the case 110). When the battery cover 120 is attached to the front end (the end on the positive side of the X axis) of the case 110, the battery cover 120 forms an outer shape like a substantially rectangular parallelepiped together with the case 110. In the interior of the battery cover 120, a battery (not illustrated) that supplies electric power to the circuit board 130 is incorporated.

The battery cover 120 has an opening 120A in a rectangular shape at the back end (a portion on the negative side of the X axis) facing the case 110. When the fitting of the convex portion 113 of the case 110 to the opening 120A, the battery cover 120 is attached to the front end (the end on the positive side of the X axis) of the case 110 and is supported by the convex portion 113 from the inside so that the battery cover 120 does not easily fall off the case 110.

The case 110 and battery cover 120 are formed from a synthetic resin material, such as an acrylonitrile butadiene styrene (ABS) resin material or a polycarbonate (PC) resin material, by being injection-molded in a certain shape.

The circuit board 130, which is disposed in the interior of the case 110, is a member that is formed from a resin material and is shaped like a flat plate. In the interior of the case 110, the circuit board 130 is fixed in a horizontal orientation with respect to the lower case 112. When various electronic parts are mounted on the circuit board 130, an integrated circuit that implements various functions of a resin molded product 10 (such as, for example, wireless communication functions and control functions) is formed. The integrated circuit operates on electric power supplied from the battery (not illustrated) incorporated in the battery cover 120. A printed circuit board (PCB), for example, is used as the circuit board 130.

### Screw Fixing Structure

Here, a screw fixing structure included in the portable device 100 will be described. As illustrated in FIGS. 2 to 4, the battery cover 120 may have a main body 122. The battery cover 120 also has a screw tightening portion 121 in a flat plate shape. The screw tightening portion 121 may protrude from the back end (the end on the negative side of the X axis) of a lower-wall portion 122A of the main body 122 and from its central portion in the left-right direction (Y-axis direction) toward the back (in the negative direction of the X axis). Particularly, in this embodiment, one end (the end on the positive side of the X axis) of the screw tightening portion 121 is linked to the main body 122 and another end (the end on the negative side of the X axis) is not linked to any member, forming a ligulate shape. The screw tightening portion 121 has a through-hole 121A in a circular shape at the central portion in plan view, the through-hole 121A extending through the screw tightening portion 121 in the up-down direction.

In a lower-wall portion 112A of the lower case 112, a concave portion 112B having substantially the same shape as the screw tightening portion 121 is formed at the front end (the end on the positive side of the X axis) and at the central portion in the left-right direction (Y-axis direction). In the concave portion 112B, a screw hole 112C is formed at the central portion in plan view, the screw hole 112C being threaded upward (in the positive direction of the Z axis).

Here, as illustrated in FIGS. 2 and 4, with the portable device 100 in an embodiment, when the battery cover 120 is attached to the front end (the end on the positive side of the X axis) of the case 110, the screw tightening portion 121 of the battery cover 120 is fitted to the interior of the concave portion 112B in the lower case 112. At this time, the through-hole 121A in the screw tightening portion 121 and the screw hole 112C in the concave portion 112B coincide with each other in plan view from below (in the negative direction of the X axis).

Therefore, with the portable device 100 in an embodiment, when a flat head screw 140 is passed through the through-hole 121A in the screw tightening portion 121 and the flat head screw 140 is then screwed into the screw hole 112C in the concave portion 112B, the screw tightening portion 121 can be screw-fixed to the concave portion 112B, as illustrated in FIG. 4.

### Detailed Description of the Structure of the Screw Tightening Portion 121

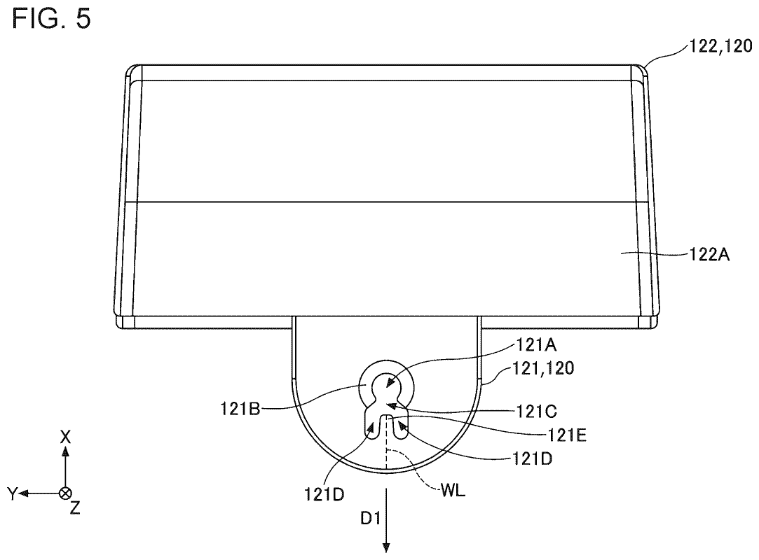

FIG. 5 is a bottom view of the battery cover 120 included in the portable device 100 in an embodiment.

As described above, the screw tightening portion 121 of the battery cover 120 has the through-hole 121A in a circular shape at the central portion in plan view, the through-hole 121A extending through the screw tightening portion 121 in the up-down direction, as illustrated in FIG. 5.

The screw tightening portion 121 has a tapered surface 121B (an example of an abutting area) formed in a circular ring shape around the through-hole 121A so as to enclose the through-hole 121A in plan view. The tapered surface 121B may have a tapered surface shape (cone shape), the diameter of which is gradually reduced in the depth direction (the positive direction of the Z axis).

Therefore, the screw tightening portion 121 can accept a tightening force applied from the bearing surface, in a conical shape, of a head 141 of the flat head screw 140 at the tapered surface 121B, which is also in a conical shape, during tightening by the flat head screw 140, and can store the head 141 of the flat head screw 140 inside the tapered surface 121B so that the head 141 does not protrude from the screw tightening portion 121.

On the screw tightening portion 121, a weld line WL extending in the front-back direction (X-axis direction) is formed at an intermediate position in the left-right direction (Y-axis direction) in a portion behind the through-hole 121A (that is, more on the negative side of the X axis than the through-hole 121A), as illustrated in FIG. 5. When the battery cover 120 is injection-molded, this weld line WL is formed because a melted resin and another melted resin have respectively flowed from one side (the positive side of the Y axis) and from another side (the negative side of the Y axis) so as to turn along the outside of the through-hole 121A and then have merged together. Therefore, the weld line WL can be represented as a melted resin merging portion or the like. The weld line WL can be found in flow analysis of molted resins for injection molding of the battery cover 120.

Since the weld line WL is formed on the screw tightening portion 121, there is the fear that stress is applied to the weld line WL during tightening by the flat head screw 140 and a crack is thereby generated along the weld line WL.

In view of this, with the portable device 100 in an embodiment, a cut portion 121C and a pair of slits 121D are formed in the screw tightening portion 121 as illustrated in FIG. 5,

The cut portion 121C is formed by cutting part of the tapered surface 121B so that the cut portion 121C extends from the through-hole 121A in a first direction D1 (the negative direction on the X axis), which is along the weld line WL.

The pair of slits 121D are formed so as to extend further away from the cut portion 121C in the first direction D1 (the negative direction of the X axis). The pair of slits 121D are symmetric with respect to the weld line WL.

The pair of slits 121D may be portions between which a protrusion 121E is formed. The cut portion 121C may link the through-hole 121A and the pair of slits 121D together.

Since the pair of slits 121D are formed, the screw tightening portion 121 has the protrusion 121E, which protrudes in a direction toward the through-hole 121A, between the pair of slits 121D. Thus, the weld line WL is present on the protrusion 121E.

Therefore, what is important here is that the cut portion 121C and the pair of slits 121D may be formed so that the head 141 of the flat head screw 140 does not abut the protrusion 121E during tightening by the flat head screw 140.

Since the tip (the end on the positive side of the X axis) of the protrusion 121E is positioned at substantially the same position as the outer circumferential portion of the head 141 of the flat head screw 140, the tip can function to position the outer circumferential portion of the head 141 of the flat head screw 140 and also functions as a stopper.

With the portable device 100 in an embodiment, since the cut portion 121C and the pair of slits 121D are formed, stress can be concentrated on the pair of slits 121D (that is, both outer sides of the weld line WL) during tightening by the flat head screw 140. Therefore, stress applied to the weld line WL on the protrusion 121E can be suppressed.

Particularly, in this embodiment, the pair of slits 121D may be formed in parallel to each other as an example of a preferred structure that can release stress applied to the weld line WL.

### EXAMPLE

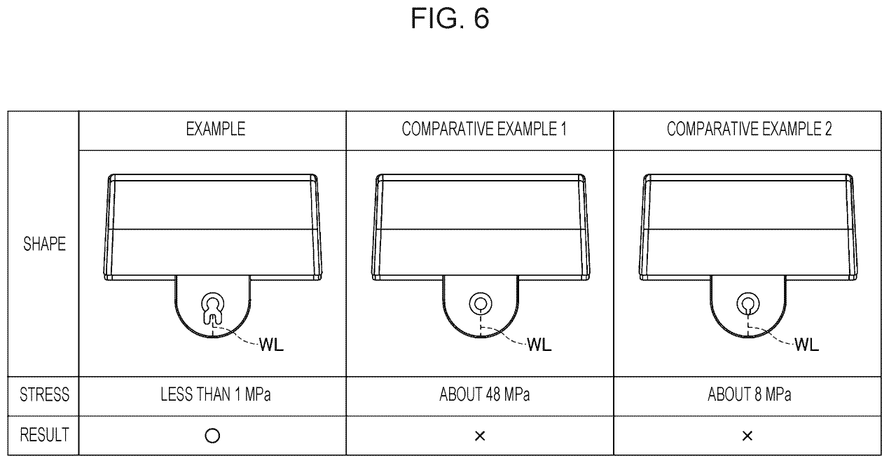

FIG. 6 illustrates an example of the battery cover 120 included in the portable device 100 in an embodiment.

In this example, the battery cover 120 illustrated in FIG. 5 was used as an example, and battery covers prepared for comparison were used as comparative example 1 and comparative example 2. For the example and comparative examples, stress applied to the weld line WL was measured through simulations and a decision was made for the possibility of a crack occurring as to whether the result is good or bad.

As comparative example 1, a battery cover that has neither a cut portion nor slit portions was used. As comparative example 2, a battery cover that has a cut portion but does not have slit portions was used.

As illustrated in FIG. 6, with comparative example 1, it was found that an extremely large stress of about 48 Mpa was applied to the weld line WL. Since the possibility of a crack occurring was extremely high, a bad (x) decision was made for the possibility of a crack occurring. A possible reason for this is that comparative example 1 has neither a cut portion nor slit portions, so stress cannot be released to any of them and the stress is thereby applied to the weld line WL in a concentrated manner.

Also, as illustrated in FIG. 6, with comparative example 2, it was found that a relatively large stress of about 8 Mpa was applied to the weld line WL. Since the possibility of a crack occurring was relatively high, a bad (x) decision was made for the possibility of a crack occurring. A possible reason for this is that comparative example 2 has a cut portion, so a certain degree of stress can be released to the cut portion, but that alone is insufficient and stress is still applied to the weld line WL in a concentrated manner.

Also, as illustrated in FIG. 6, with the example, it was found that only an extremely small stress of less than 1 Mpa was applied to the weld line WL. Since the possibility of a crack occurring was extremely low, a good (o) decision was made for the possibility of a crack occurring. A possible reason for this is that the example has the cut portion 121C and the pair of slits 121D, so substantially all of stress can be released to the pair of slits 121D.

### First Variation

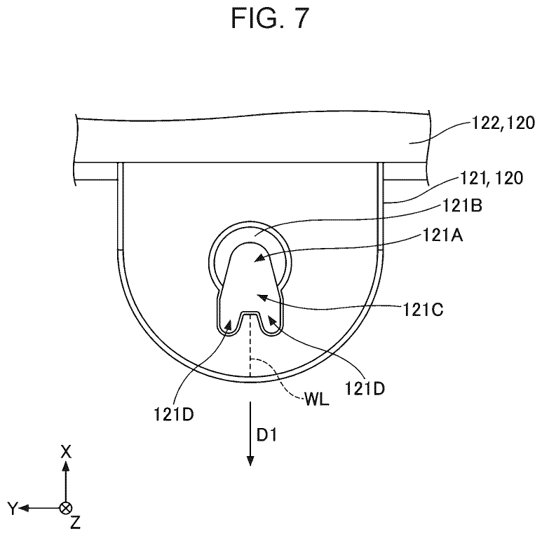

FIG. 7 illustrates a first variation of the screw tightening portion 121 included in the portable device 100 in an embodiment. The screw tightening portion 121 illustrated in FIG. 7 is the first variation of the screw tightening portion 121 illustrated in FIG. 5. The screw tightening portion 121 illustrated in FIG. 7 differs from the screw tightening portion 121 illustrated in FIG. 5 in that the groove width of the cut portion 121C is expanded and the cut portion 121C is prolonged in the first direction D1.

The inventors confirmed through simulations that even when the groove width of the cut portion 121C is expanded and the cut portion 121C is prolonged in the first direction D1 in this way, substantially all of stress can be released to the pair of slits 121D as when the pair of slits 121D are formed in parallel to each other (see the structure in FIG. 5), so only an extremely small stress of less than 1 Mpa is applied to the weld line WL.

### Second Variation

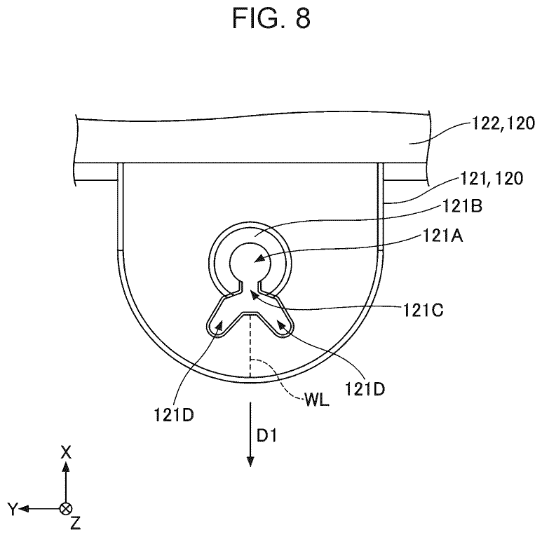

FIG. 8 illustrates a second variation of the screw tightening portion 121 included in the portable device 100 in an embodiment. The screw tightening portion 121 illustrated in FIG. 8 is the second variation of the screw tightening portion 121 illustrated in FIG. 5. With the screw tightening portion 121 illustrated in FIG. 8, the pair of slits 121D may be formed in a radial shape (that is, a shape in which as the pair of slits 121D extend in the first direction D1 (the negative direction of the X axis), the spacing between them is gradually increased). In this regard, the screw tightening portion 121 illustrated in FIG. 8 differs from the screw tightening portion 121 illustrated in FIG. 5.

The inventors confirmed through simulations that even when the pair of slits 121D are formed in a radial shape in this way, substantially all of stress can be released to the pair of slits 121D as when the pair of slits 121D are formed in parallel to each other (see the structure in FIG. 5), so only an extremely small stress of less than 1 Mpa is applied to the weld line WL.

This completes the detailed description of an embodiment of the present invention. However, the present invention is not limited to the embodiment. Various variations and modifications are possible without departing from the intended scope, described in the claims, of the present invention.

For example, in the above embodiment, the left-right width (the width in the Y-axis direction) of the screw tightening portion 121 has been smaller than the left-right width of the main body 122. However, this is not a limitation; the left-right width (the width in the Y-axis direction) of the screw tightening portion 121 may be equal to the left-right width of the main body 122. Even in this case, a similar effect of suppressing stress applied to the weld line WL is obtained by forming the cut portion 121C and the pair of slits 121D.

From the viewpoint of suppressing stress applied to the weld line WL, it is preferable for the pair of slits 121D to be formed at least in a range in which they form an acute angle with respect to the center of the through-hole 121A, as with the structures, illustrated in FIGS. 5, 7, and 8, which are all applicable.

Also, in the above embodiment, an example has been explained in which the flat head screw 140 is used to fix the screw tightening portion 121. However, this is not a limitation; even when another type of screw (a screw the bearing surface of which is not in a tapered shape but in a flat-surface shape) is used to fix the screw tightening portion 121, a similar effect of suppressing stress applied to the weld line WL is obtained by forming the cut portion 121C and the pair of slits 121D.

This international application claims priority based on Japanese Patent Application No. 2022-123571 filed on Aug. 2, 2022, and the entire contents of the application are incorporated in this international application.

What is claimed is:

1. A resin molded product comprising a screw tightening portion in a flat-plate shape, wherein
the screw tightening portion has
a through-hole, through which a screw passes,
an abutting area allocated around the through-hole, a head of the screw abutting the abutting area,
a cut portion formed so as to extend from the through-hole in a first direction, which is along a weld line, the cut portion being formed by cutting out part of the abutting area, and
a pair of slits formed so as to further extend from the cut portion in the first direction, the pair of slits being symmetric with respect to the weld line.

2. The resin molded product according to claim 1, wherein the pair of slits are formed in parallel to each other.

3. The resin molded product according to claim 1, wherein the pair of slits are formed in a radial shape.

4. The resin molded product according to claim 1, wherein the pair of slits are formed in a range in which the pair of slits form an acute angle with respect to a center of the through-hole.

5. The resin molded product according to claim 1, further comprising a main body, wherein
the screw tightening portion is formed so as to extend from the main body in the first direction.

6. The resin molded product according to claim 1, wherein the abutting area is a tapered surface forming a cone shape.

7. The resin molded product according to claim 1, wherein:
the pair of slits are portions between which a protrusion is formed; and
the cut portion links the through-hole and the pair of slits together.

8. The resin molded product according to claim 1, wherein:
the pair of slits are portions between which a protrusion is formed; and
the cut portion and the pair of slits are formed so that the head of the screw does not abut the protrusion during tightening by the screw.
